(19) United States
(12) Patent Application Publication
(10) Pub. No.: US 2025/0234708 A1
(43) Pub. Date: Jul. 17, 2025

(54) DISPLAY DEVICE

(71) Applicant: Samsung Display Co., LTD., Yongin-si (KR)

(72) Inventors: Moon Sung KIM, Yongin-si (KR); Yeo Myeong KIM, Yongin-si (KR); Ki Young YEON, Yongin-si (KR); Jae Bum HAN, Yongin-si (KR)

(73) Assignee: Samsung Display Co., LTD., Yongin-si (KR)

(21) Appl. No.: 18/813,644

(22) Filed: Aug. 23, 2024

(30) Foreign Application Priority Data
Jan. 12, 2024 (KR) 10-2024-0005189

(51) Int. Cl. H10K 59/121; H10K 59/126; H10K 59/131; H10K 102/00

(52) U.S. Cl. CPC H10K 59/1216; H10K 59/126; H10K 59/131; H10K 2102/351

(57) ABSTRACT

A display device comprises a first barrier layer disposed on a substrate, a first conductive layer disposed on the first barrier layer and including a first light blocking layer and a first capacitor electrode, a protective layer disposed on the first conductive layer and including a first additive, a second barrier layer disposed on the protective layer, a second conductive layer disposed on the second barrier layer, a buffer layer disposed on the second conductive layer, an active layer disposed on the buffer layer and including an oxide semiconductor, a gate insulating layer disposed on the active layer, and a third conductive layer disposed on the gate insulating layer and connected to the first capacitor electrode, wherein the first conductive layer includes a first metal layer, a second metal layer disposed on the first metal layer, and a third metal layer disposed on the second metal layer.

### CROSS-REFERENCE TO RELATED APPLICATION

This application claims priority to and benefits of Korean Patent Application No. 10-2024-0005189 under 35 U.S.C. § 119, filed on Jan. 12, 2024 in the Korean Intellectual Property Office (KIPO), the contents of which in its entirety are incorporated herein by reference.

### BACKGROUND

### 1. Technical Field

The disclosure relates to a display device.

### 2. Description of the Related Art

As an information society develops, the demand for a display device for displaying an image is increasing in various forms. For example, the display device has been applied to various electronic devices such as smartphones, digital cameras, laptop computers, navigation devices, and smart televisions.

The display device may be a flat panel display device such as a liquid crystal display device, a field emission display device, or a light emitting display device. The light emitting display device includes an organic light emitting display device including an organic light emitting element, an inorganic light emitting display device including an inorganic light emitting element such as an inorganic semiconductor, and a subminiature light emitting display device including a subminiature light emitting element.

The organic light emitting element may include two opposing electrodes and a light emitting layer interposed therebetween. The light emitting layer receives electrons and holes from the two electrodes and recombines the electronic and the holes to generate excitons, and the generated excitons change from an excited state to a ground state, thereby emitting light.

The organic light emitting display device including the organic light emitting element may be configured in a light weight and thin shape with low power consumption because of not requiring a light source such as a backlight unit, and has also attracted attention as a next-generation display device because of having high-quality characteristics such as a wide viewing angle, high luminance and contrast, and a fast response speed.

### SUMMARY

Aspects of the disclosure provide a display device capable of improving deterioration in characteristics of a thin film transistor by preventing diffusion of hydrogen.

The technical objectives to be achieved by the disclosure are not limited to those described herein, and other technical objectives that are not mentioned herein would be clearly understood by a person skilled in the art from the description of the disclosure.

However, aspects of the disclosure are not restricted to those set forth herein. The above and other aspects of the disclosure will become more apparent to one of ordinary skill in the art to which the disclosure pertains by referencing the detailed description of the disclosure given below.

According to an aspect of the disclosure, a display device comprises a first barrier layer disposed on a substrate, a first conductive layer disposed on the first barrier layer and including a first light blocking layer and a first capacitor electrode, a protective layer disposed on the first conductive layer and including a first additive, a second barrier layer disposed on the protective layer, a second conductive layer disposed on the second barrier layer, a buffer layer disposed on the second conductive layer, an active layer disposed on the buffer layer and including an oxide semiconductor, a gate insulating layer disposed on the active layer, and a third conductive layer disposed on the gate insulating layer and connected to the first capacitor electrode, wherein the first conductive layer includes a first metal layer, a second metal layer disposed on the first metal layer, and a third metal layer disposed on the second metal layer.

In an embodiment, the first metal layer may include titanium, the second metal layer includes aluminum, and the third metal layer includes titanium.

In an embodiment, the second metal layer may have a thickness greater than each of the first metal layer and the third metal layer.

In an embodiment, a thickness of the first metal layer may be in a range of about 100 to about 300 Å, and a thickness of the third metal layer may be in a range of about 300 to about 700 Å.

In an embodiment, the first additive may include fluorine and chlorine.

In an embodiment, a concentration of fluorine in the protective layer may be greater than a concentration of chlorine.

In an embodiment, a concentration of fluorine and a concentration of chlorine in the protective layer may increase from an upper surface to a lower surface of the protective layer.

In an embodiment, the protective layer may contain silicon nitride including fluorine and chlorine.

In an embodiment, the first light blocking layer and the first capacitor electrode may be separated from each other, and the first capacitor electrode has an island pattern.

According to an aspect of the disclosure, a display device comprises a first barrier layer disposed on a substrate, a second barrier layer disposed on the first barrier layer, a first conductive layer disposed on the second barrier layer and including a first light blocking layer and a first capacitor electrode, a third barrier layer disposed on the first conductive layer, a second conductive layer disposed on the third barrier layer, a buffer layer disposed on the second conductive layer, an active layer disposed on the buffer layer and including an oxide semiconductor, a gate insulating layer disposed on the active layer, and a third conductive layer disposed on the gate insulating layer and connected to the first capacitor electrode, wherein the first conductive layer includes a first metal layer and a second metal layer disposed on the first metal layer.

In an embodiment, the first barrier layer may include silicon nitride, and the second barrier layer includes silicon oxide.

In an embodiment, the first metal layer may include aluminum, and the second metal layer may include titanium.

In an embodiment, a thickness of the second metal layer may be in a range of about 300 to about 700 Å.

In an embodiment, the display device may further comprise a third metal layer disposed on a lower portion of the first metal layer, wherein the third metal layer may include titanium.

According to an aspect of the disclosure, a display device comprises a first barrier layer disposed on a substrate, a first conductive layer disposed on the first barrier layer and including a first light blocking layer and a first capacitor electrode, a second barrier layer disposed on the first conductive layer, a second conductive layer disposed on the second barrier layer, a buffer layer disposed on the second conductive layer, an active layer disposed on the buffer layer and including an oxide semiconductor, a gate insulating layer disposed on the active layer, and a third conductive layer disposed on the gate insulating layer and connected to the first capacitor electrode, wherein the third conductive layer includes a first metal layer, a second metal layer disposed on the first metal layer, and a third metal layer disposed on the second metal layer.

In an embodiment, the first metal layer may include titanium, the second metal layer may include aluminum, and the third metal layer may include titanium.

In an embodiment, the second metal layer may include a thickness greater than each of the first metal layer and the third metal layer.

In an embodiment, a thickness of the first metal layer may be in a range of about 200 to about 500 Å, and a thickness of the third metal layer may be in a range of about 300 to about 700 Å.

In an embodiment, the active layer may include indium-gallium-zinc oxide, indium-gallium-zinc-tin oxide, or indium-gallium oxide.

In an embodiment, the first light blocking layer and the first capacitor electrode may be separated from each other, and the first capacitor electrode may have an island pattern.

The display device according to an embodiment may block hydrogen diffusing from a first barrier layer. Accordingly, changes in characteristics of the transistor may be prevented and operating characteristics of the transistor may be improved or stabilized.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view illustrating a display device according to an embodiment;

FIG. 2 is a schematic plan view illustrating a display panel of FIG. 1;

FIG. 3 is a schematic diagram of an equivalent circuit illustrating a pixel according to an embodiment;

FIG. 4 is a schematic cross-section view illustrating a display panel according to an embodiment;

FIG. 5 is a schematic partial plan view of a pixel of the display device according to an embodiment;

FIG. 6 is a schematic cross-sectional view taken along line Q1-Q1′ of FIG. 5;

FIG. 7 is a schematic enlarged cross-sectional view of area A of FIG. 6;

FIG. 8 is a graph illustrating measured concentrations of fluorine and chlorine in a first protective layer and a first conductive layer;

FIGS. 9 to 11 are schematic cross-sectional views illustrating each process of a method for manufacturing a first protective layer according to an embodiment;

FIG. 12 is a schematic cross-sectional view illustrating a display device according to another embodiment;

FIG. 13 is a schematic cross-sectional view illustrating another example of the display device according to another embodiment; and

FIG. 14 is a schematic cross-sectional view illustrating a display device according to still another embodiment.

### DETAILED DESCRIPTION OF THE EMBODIMENTS

The disclosure will now be described more fully hereinafter with reference to the accompanying drawings, in which some embodiments of the disclosure are shown. This disclosure may, however, be embodied in different forms and should not be construed as limited to the embodiments set forth herein. Rather, these embodiments are provided so that this disclosure will be more thorough and complete, and will convey the scope of the disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

Each of the features of the various embodiments of the disclosure may be combined or combined with each other, in part or in whole, and technically various interlocking and driving are possible. Each embodiment may be implemented independently of each other or may be implemented together in an association.

Hereinafter, embodiments of the disclosure will be described with reference to the accompanying drawings.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

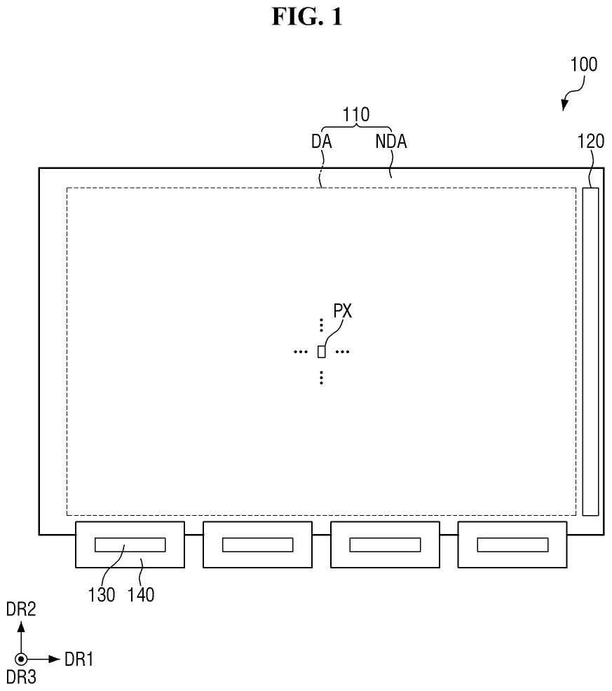

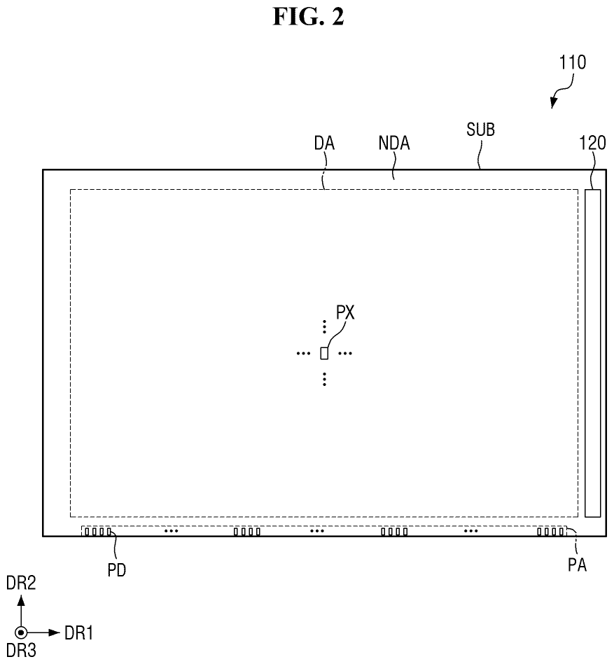

FIG. 1 is a schematic plan view illustrating a display device according to an embodiment. FIG. 2 is a schematic plan view illustrating a display panel of FIG. 1.

Referring to FIGS. 1 and 2, a display device 100 may be a device that displays a moving image or a still image, and may be used as a display screen of each of various products such as a television, a laptop computer, a monitor, a billboard, and an Internet of Things (IoT) device as well as portable electronic devices such as a mobile phone, a smartphone, a tablet personal computer (PC), a smartwatch, a watch phone, a mobile communication terminal, an electronic organizer, an electronic book, a portable multimedia player (PMP), a navigation device, and an ultra mobile PC (UMPC). These are presented merely as examples, and the display device 100 may also be employed in other electronic devices.

In an embodiment, the display device 100 may be a light emitting display device such as an organic light emitting display device using an organic light emitting diode, a quantum dot light emitting display device including a quantum dot light emitting layer, an inorganic light emitting display device including an inorganic semiconductor, and a micro or nano light emitting display device including a micro or nano light emitting diode (LED), but is not limited thereto. For example, the display device 100 may be a type of display device other than the light emitting display device. Hereinafter, embodiments in which the display device 100 is a light emitting display device (e.g., an organic light emitting display device) are disclosed.

The display device 100 may include a display panel 110 including pixels PX, and a first driver 120 and a second driver 130 that supply driving signals to the pixels PX. The display device 100 may further include additional components. For example, the display device 100 may further include a power supply or power supply unit for supplying power voltages to the pixels PX, the first driver 120, and/or the second driver 130, a timing controller or timing control unit for controlling operations of the first driver 120 and/or the second driver 130.

The display panel 110 may include a display area DA and a non-display area NDA. The display area DA may be an area that includes the pixels PX and displays an image. For example, the display area DA may include pixel areas in which each pixel PX is disposed. The non-display area NDA may be the remaining area excluding the display area DA, and an image may not be displayed in the non-display area NDA. In an embodiment, the non-display area NDA may be positioned around the display area DA and surround the display area DA.

In FIGS. 1 and 2, a first direction DR1, a second direction DR2, and a third direction DR3 are defined. In an embodiment, the first direction DR1 may be a horizontal direction of the display panel 110, and the second direction DR2 may be a vertical direction of the display panel 110. The third direction DR3 may be a thickness direction of the display panel 110.

In an embodiment, the display panel 110 may have a rectangular shape in plan view. FIGS. 1 and 2 illustrate the display panel 110 with a horizontal length longer than a vertical length, but the shape of the display panel 110 is not limited thereto. For example, the display panel 110 may have a shape in which the vertical length is longer than the horizontal length, or may have a square shape, etc. The display panel 110 may include angled corners or rounded corners.

The planar shape of the display panel 110 is not limited to the illustrated quadrangular shape, and other shapes may also be applied. For example, the display panel 110 may have a non-quadrangular other polygonal shape, a circular shape, an oval shape, an irregular shape, or other shapes in plan view.

In an embodiment, the display panel 110 may be substantially flat on a plane defined by the first direction DR1 and the second direction DR2 and may have a uniform thickness in the third direction DR3. As another example, the display panel 110 may also be provided in a three-dimensional shape having a curved surface, etc.

The display panel 110 may be provided as a rigid panel so as not to be substantially deformed, or may be provided as a flexible panel that may be deformed into a shape such as being folded, bent, or rolled at least in one portion. The display panel 110 may be provided to the display device 100 in an unbent state or may be provided to the display device 100 in a bent state in some sections.

The display panel 110 may include a substrate SUB and pixels PX disposed on the substrate SUB. The pixels PX may be disposed in the display area DA on the substrate SUB.

The substrate SUB is a base member for manufacturing or providing the display panel 110 and may form a base surface of the display panel 110. The substrate SUB may include a display area DA and a non-display area NDA around the display area DA.

The display area DA may have various shapes depending on embodiments. For example, the display area DA may have a square shape, a non-quadrangular other polygonal shape, a circular shape, an oval shape, an irregular shape, or other shapes. In an embodiment, the display area DA may have a shape that matches the shape of the display panel 110.

The pixels PX may be provided and/or arranged in the display area DA. For example, the display area DA may include pixel areas in which each pixel PX is disposed.

In an embodiment, the display device 100 may be a light emitting display device, and each pixel PX may include a light emitting element positioned in each light emitting area and a pixel circuit connected to the light emitting element. In describing the embodiments, “connection” may include electrical connection and/or physical connection. Each pixel circuit may include transistors (e.g., transistors, including a driving transistor that generates a driving current corresponding to a data signal, and at least one switching transistor), and at least one capacitor (e.g., a capacitor including a storage capacitor).

The non-display area NDA may include a pad area PA in which pads PD are disposed. In an embodiment, the non-display area NDA may further include a driving circuit area positioned on at least one side of the display area DA. At least one driver, pads PD, and/or lines may be disposed in the non-display area NDA.

At least one driver for driving the pixels PX, or a portion of the driver may be disposed in the driving circuit area. As an example, circuit elements constituting the first driver 120 (e.g., driver transistors and driver capacitors constituting stage circuits of the first driver 120) may be disposed in the driving circuit area on the substrate SUB. In an embodiment, the circuit elements of the first driver 120 may be formed within the display panel 110 together with the pixels PX. In an embodiment, the driver transistors provided in the first driver 120 may be transistors of substantially the same or similar type and/or structure as the transistors provided in the pixels PX, and may be formed simultaneously with the transistors of the pixels PX.

The pads PD may be disposed in the pad area PA. At least one circuit board 140 may be disposed and/or bonded onto the pad area PA. In an embodiment, one or more circuit boards 140 connected to different pads PD may be disposed on the pad area PA. The pads PD may include signal pads and/or power pads for transmitting driving signals and power voltages necessary for driving the pixels PX and/or the first driver 120 to the inside of the display panel 110.

The first driver 120 and the second driver 130 may generate driving signals for controlling an operation timing and luminance of the pixels PX, and supply the driving signals to the pixels PX. For example, the first driver 120 may be a gate driver including a scan driver, and may be connected to the pixels PX through the respective gate lines. The first driver 120 may supply respective gate signals (e.g., control signals that control driving timing of the pixels PX, including scan signals and/or emission control signal) to the pixels PX. The second driver 130 may be a data driver including source driver circuits and may be connected to the pixels PX through the respective data lines. The second driver 130 may supply respective data signals to the pixels PX.

In an embodiment, at least one of the first driver 120 and the second driver 130, or a portion of the at least one driver, may be embedded in the display panel 110. For example, the first driver 120 or a portion of the first driver 120 may be disposed on the substrate SUB of the display panel 110 and may be disposed and/or formed in the non-display area NDA.

It is illustrated in FIG. 1 that the first driver 120 is formed on a side of the display area DA (e.g., the non-display area NDA on the right side of the display area DA), but the embodiments are not limited thereto. For example, the first driver 120 may be positioned only on another of the display area DA (e.g., the non-display area NDA on the left side of the display area DA), or may be positioned on both sides of the display area DA (e.g., non-display areas NDA on the left and right sides of the display area DA). As another example, a portion of the first driver 120 may be positioned in the non-display area NDA, and another portion of the first driver 120 may be positioned in the non-light emitting area (e.g., an area between the light emitting areas of the pixels PX) inside the display area DA.

In an embodiment, the other of the first driver 120 and the second driver 130, or a portion of the other driver, may be disposed or formed outside the display panel 110 and may be electrically connected to the display panel 110. For example, the second driver 130 may be implemented with one or more integrated circuit chips and may be disposed on the circuit boards 140 electrically connected to the pixels PX of the display panel 110. The second driver 130 may be implemented with at least one integrated circuit chip and may be mounted on the non-display area NDA of the display panel 110.

The circuit board 140 may be connected to the display panel 110 through pads PD. In an embodiment, the circuit board 140 may be a flexible film such as a flexible printed circuit board (FPCB), a printed circuit board (PCB), or a chip on film (COF), but is not limited thereto. In an embodiment, the circuit board 140 may be connected to the timing controller and/or the power supply through another circuit board or a connector.

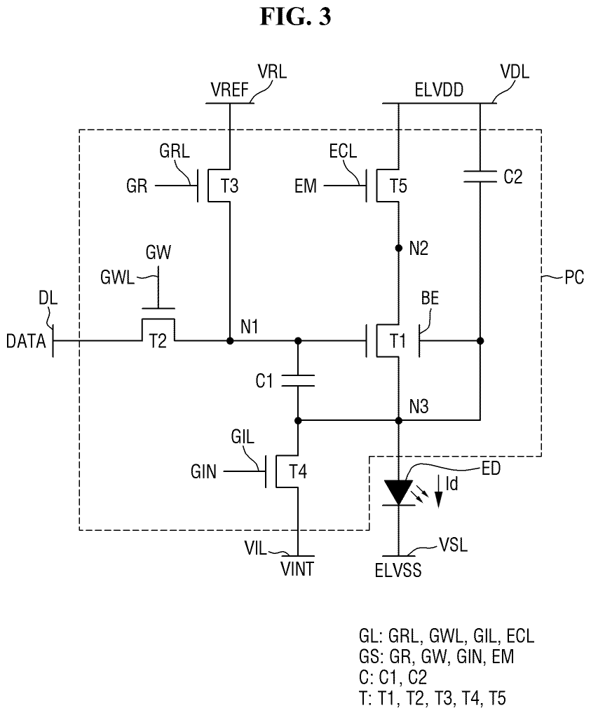

FIG. 3 is a schematic diagram of an equivalent circuit illustrating a pixel according to an embodiment. For example, FIG. 3 illustrates a pixel PX of a light emitting display device including a light emitting element ED. In addition to the embodiment of FIG. 3, the type and/or structure of the pixel PX that may be included in the display device 100 may be variously changed depending on the embodiments.

Referring to FIG. 3 in addition to FIGS. 1 and 2, the pixel PX may include a light emitting element ED and a pixel circuit PC connected to the light emitting element ED. The light emitting element ED is a light source of the pixel PX and may be, for example, an organic light emitting diode, but is not limited thereto. The pixel circuit PC may control the light emitting timing and luminance of the light emitting element ED.

The pixel circuit PC may include transistors T and at least one capacitor C. For example, the pixel circuit PC may include first to fifth transistors T1 to T5, and first and second capacitors C1 and C2. FIG. 3 illustrates an embodiment in which all transistors T are N-type transistors, but the type of transistors T is not limited thereto. For example, at least one transistor T may also be formed as a P-type transistor.

The pixel circuit PC may supply a driving current Id to the light emitting element ED in response to the driving signals supplied from the first driver 120 and the second driver 130. For example, the pixel circuit PC may supply the driving current Id to the light emitting element ED in response to each gate signal GS supplied from the first driver 120 through each gate line GL, and a data signal DATA supplied from the second driver 130 through the data line DL.

The first transistor T1 may be a driving transistor of the pixel PX whose size of a drain-source current (e.g., the driving current Id) is determined depending on a gate-source voltage. The second, third, fourth, and fifth transistors T2, T3, T4, and T5 may be switching transistors that are turned on or off depending on respective gate-source voltages. Depending on the type (e.g., P-type or N-type transistor) and/or operating conditions of each of the first to fifth transistors T1 to T5, a first electrode of each of the first to fifth transistors T1 to T5 may be a drain electrode (or a drain region) or a source electrode (or source region), and a second electrode thereof may be an electrode different from the first electrode. For example, in case that the first electrode is a drain electrode, the second electrode may be a source electrode.

The pixel PX may be connected to a first gate line GWL transmitting a first gate signal GW (e.g., a scan signal), a second gate line GIL transmitting a second gate signal GIN, a third gate line GRL transmitting a third gate signal GR, an emission control line ECL transmitting an emission control signal EM, and a data line DL transmitting a data signal DATA. In addition, the pixel PX may be connected to a first power line VDL transmitting a first pixel voltage ELVDD (also referred to as “first pixel power voltage”), and a second power line VSL transmitting a second pixel voltage ELVSS (also referred to as “second pixel power voltage”). In an embodiment, the pixel PX may be further connected to an initialization power line VIL transmitting an initialization voltage VINT (also referred to as “third pixel power voltage”), and a reference power line VRL transmitting a reference voltage VREF (also referred to as “fourth pixel power voltage”).

In an embodiment, the first to fifth transistors T1 to T5 may be positioned in respective pixel areas, and may be oxide transistors (also referred to as “oxide semiconductor transistors”) including an oxide semiconductor (e.g., an oxide semiconductor material). For example, an active layer of each of the first to fifth transistors T1 to T5 may include an oxide semiconductor. However, the embodiments are not limited thereto. For example, at least one transistor T may be formed of other semiconductor materials (e.g., amorphous silicon or polysilicon) other than the oxide semiconductor.

The oxide semiconductor has high carrier mobility and low leakage current, and accordingly, even if a driving time of the oxide transistor becomes longer, a voltage drop may not significantly occur. For example, the pixel PX including the oxide transistor may be driven at a low frequency because the luminance and/or color of an image does not change significantly due to a voltage drop even when driven at the low frequency. In case that the first to fifth transistors T1 to T5 are formed as the oxide transistors, leakage current of the pixel PX may be reduced or prevented and power consumption may be reduced.

Since the oxide semiconductor is sensitive to light, the amount of current, etc. may vary due to external light. In an embodiment, the external light may be blocked by disposing a light blocking pattern or a light blocking electrode (e.g., a bottom electrode or a back-gate electrode) on a lower portion of the active layer included in at least one transistor T. Accordingly, operating characteristics of the transistor T may be stabilized.

The first transistor T1 may include a gate electrode connected to a first node N1, a first electrode (e.g., a drain electrode) connected to a second node N2, and a second electrode (e.g., a source electrode) connected to a third node N3. The first electrode of the first transistor T1 may be connected to the first power line VDL via the fifth transistor T5, and the second electrode thereof may be connected to the light emitting element ED. The first transistor T1 may control the size of the driving current Id (e.g., amount of current) flowing to the light emitting element ED in response to the data signal DATA transmitted to the first node N1.

In an embodiment, the first transistor T1 may further include a bottom electrode BE connected to the third node N3 (e.g., a bottom-gate electrode or a back-gate electrode of the first transistor T1). In case that the bottom electrode BE of the first transistor T1 is connected to the third node N3 to form the first transistor T1 as a transistor with a double gate structure (e.g., a double gate with a source-sync structure), the operating characteristics of the first transistor T1 may be improved.

The second transistor T2 may include a gate electrode connected to the first gate line GWL, a first electrode connected to the data line DL, and a second electrode connected to the first node N1. The second transistor T2 may be turned on by the first gate signal GW (e.g., the first gate signal GW of a gate-on voltage) transmitted to the first gate line GWL and connect the data line DL and the first node N1 to each other. Accordingly, the data signal DATA transmitted to the data line DL may be transmitted to the first node N1.

The third transistor T3 may include a gate electrode connected to the third gate line GRL, a first electrode connected to the reference power line VRL, and a second electrode connected to the first node N1. The third transistor T3 may be turned on by the third gate signal GR transmitted to the third gate line GRL and transmit the reference voltage VREF transmitted to the reference power line VRL to the first node N1.

The fourth transistor T4 may include a gate electrode connected to the second gate line GIL, a first electrode connected to the third node N3, and a second electrode connected to the initialization power line VIL. The fourth transistor T4 may be turned on by the second gate signal GIN transmitted to the second gate line GIL and transmit the initialization voltage VINT transmitted to the initialization power line VIL to the third node N3.

The fifth transistor T5 may include a gate electrode connected to the emission control line ECL, a first electrode connected to the first power line VDL, and a second electrode connected to the second node (or the first electrode of the first transistor T1). The fifth transistor T5 may be turned on by the emission control signal EM (e.g., an emission control signal EM of a gate-on voltage) transmitted to the emission control line ECL and control a light emitting timing of the pixel PX.

Each of the second to fifth transistors T2 to T5 may or may not include a bottom electrode. In an embodiment, at least one switching transistor of the second to fifth transistors T2 to T5 may include a bottom electrode, and the bottom electrode of the at least one switching transistor may be connected to the gate electrode of the corresponding switching transistor. In case that the bottom electrode of the switching transistor is connected to the gate electrode, the off-characteristics and switching speed of the switching transistor may be improved, an additional voltage tolerance range thereof may be secured, leakage current thereof may be reduced, and voltage stability thereof may be improved. As an example, by forming a switching transistor formed as an oxide transistor with a short channel length in a double gate structure such as a gate-sink structure, the operating characteristics of the switching transistor may be improved.

The first capacitor C1 may be connected between the first node N1 and the third node N3. The first capacitor C1 is a storage capacitor of the pixel PX and may store a threshold voltage of the first transistor T1 and a voltage corresponding to the data signal DATA (e.g., data voltage).

The second capacitor C2 may be connected between the first power line VDL and the third node N3. In an embodiment, the capacity of the second capacitor C2 may be smaller than the capacity of the first capacitor C1.

The light emitting element ED may be connected between the third node N3 and the second power line VSL. For example, the light emitting element ED may include a first electrode (e.g., an anode electrode) connected to the third node N3, a second electrode (e.g., a cathode electrode) facing the first electrode and connected to the second power line VSL, and a light emitting layer interposed between the first electrode and the second electrode. In an embodiment, the first electrode of the light emitting element ED may be an individual electrode provided individually to each pixel PX, and the second electrode of the light emitting element ED may be a common electrode shared by the pixels PX. The light emitting element ED may emit light with a luminance corresponding to the driving current Id while the driving current Id is supplied from the pixel circuit PC.

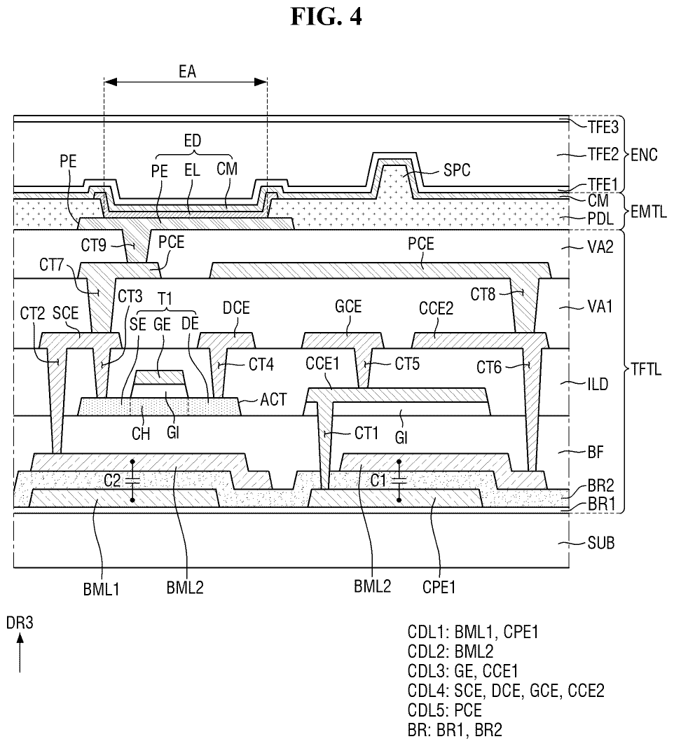

FIG. 4 is a schematic cross-section view illustrating a display panel according to an embodiment. For example, FIG. 4 illustrates a portion of the display area DA of the display panel 110. FIG. 4 illustrates a light emitting display panel including an emitting element ED (e.g., an organic light emitting diode), as an example of the display panel 110 to which the embodiments may be applied.

As illustrated in FIG. 4, the display device 100 may include a substrate SUB, a thin film transistor layer TFTL, a light emitting element layer EMTL, and an encapsulation layer ENC. The thin film transistor layer TFTL, the light emitting element layer EMTL, and the encapsulation layer ENC may be sequentially disposed on the substrate SUB along the third direction DR3. Here, the thin film transistor layer TFTL may include the first transistor T1, the second transistor T2, the third transistor T3, the fourth transistor T4, the first capacitor C1, and/or the second capacitor C2 described above.

The substrate SUB may be a rigid substrate or may be a flexible substrate capable of being bent, folded, rolled, or the like. The substrate SUB may be made of an insulating material such as glass, quartz, or a polymer resin. Examples of the polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), or a combination thereof. As another example, the substrate SUB may also include a metal material.

A first barrier layer BR1 may be disposed on the substrate SUB. The first barrier layer BR1 may be disposed on an entire surface of the substrate SUB. The first barrier layer BR1 may be a film for protecting the transistors T1 to T3 of the thin film transistor layer TFTL and the light emitting layer EL of the light emitting element layer EMTL from moisture permeating through the substrate SUB that is vulnerable to moisture permeation. The first barrier layer BR1 may be formed of one or more inorganic films alternately stacked. For example, the barrier layer BR may be formed as a multi-film in which one or more inorganic films of a silicon nitride layer, a silicon oxynitride layer, a silicon oxide layer, a titanium oxide layer, and an aluminum oxide layer are alternately stacked.

A first conductive layer CDL1 may be disposed on the first barrier layer BR1. The first conductive layer CDL1 may include a first light blocking layer BML1 and a first capacitor electrode CPE1. The first light blocking layer BML1 and the first capacitor electrode CPE1 may be separated from each other. For example, the first light blocking layer BML1 may extend in the first direction DR1 and be continuously disposed in the plurality of pixels PX, and the first capacitor electrode CPE1 may be spaced apart from the first light blocking layer BML1 and may have an island pattern. A description thereof will be provided below.

The first conductive layer CDL1 may be made of a metal material such as titanium (Ti), aluminum (Al), chromium (Cr), or molybdenum (Mo). The first conductive layer CDL1 may be supplied with static power. For example, the first light blocking layer BML1 and the first capacitor electrode CPE1 are not electrically floating, and electrical characteristics of the transistors on the first light blocking layer BML1 and the first capacitor electrode CPE1 may be stabilized.

A second barrier layer BR2 may be disposed on the first conductive layer CDL1. For example, the second barrier layer BR2 may be disposed on the first light blocking layer BML1 and the first capacitor electrode CPE1. The second barrier layer BR2 may have the same material and configuration as the first barrier layer BR1 described above.

A second conductive layer CDL2 may be disposed on the second barrier layer BR2. The second conductive layer CDL2 may include a second light blocking layer BML2. A portion of the second light blocking layer BML2 may be disposed on the second barrier layer BR2 to overlap the first light blocking layer BML1, and another portion thereof may be disposed on the second barrier layer BR2 to overlap the first capacitor electrode CPE1. Therefore, the portion of the second light blocking layer BML2 that overlaps the first capacitor electrode CPE1 acts as a second capacitor electrode, and the first capacitor C1 may be formed in an area where the first capacitor electrode CPE1 and the second light blocking layer BML2 overlap. The second capacitor C2 may be formed in an area of the second light blocking layer BML2 that overlaps the first light blocking layer BML1.

A buffer layer BF may be disposed on the second conductive layer CDL2. For example, the buffer layer BF may be disposed on the second light blocking layer BML2. The buffer layer BF may be a layer for protecting the transistors T1 to T5 of the thin film transistor layer TFTL and the light emitting layer EL of the light emitting element layer EMTL from moisture permeating through the substrate SUB that is vulnerable to moisture permeation. The buffer layer BF may include one or more inorganic films that are alternately stacked. For example, the buffer layer BF may be formed as a multi-film in which one or more inorganic films of a silicon nitride layer, a silicon oxynitride layer, a silicon oxide layer, a titanium oxide layer, and an aluminum oxide layer are alternately stacked.

An active layer ACT may be disposed on the buffer layer BF. For example, the active layer ACT may be disposed on the buffer layer BF to overlap the second light blocking layer BML2 of the second conductive layer CDL2. The active layer ACT may be an oxide-based active layer ACT. For example, the active layer ACT may be an oxide semiconductor including indium-gallium-zinc-oxide (IGZO), indium-gallium oxide (IGO), or indium-gallium-zinc-tin oxide (IGZTO).

A gate insulating layer GI may be disposed on the active layer ACT and the buffer layer BF, respectively. For example, the gate insulating layer GI may be disposed on a channel region CH of the active layer ACT to overlap the channel region CH. The gate insulating layer GI may be disposed on the buffer layer BF to overlap the second conductive layer CDL2.

In an embodiment, the gate insulating layer GI may include at least one of tetraethoxysilane (TetraEthylOrthoSilicate, TEOS), silicon nitride (SiNx), and silicon oxide (SiO₂). As an example, the gate insulating layer GI may have a double film structure in which a silicon nitride film having a thickness of about 40 nm and a tetraethoxysilane film having a thickness of about 80 nm are sequentially stacked.

A third conductive layer CDL3 may be disposed on the gate insulating layer GI. The third conductive layer CDL3 may include a gate electrode GE and a first capacitor connection electrode CCE1. The gate electrode GE and the first capacitor connection electrode CCE1 may be integrally formed. The gate electrode GE may be disposed on the gate insulating layer GI to overlap the channel region CH, and the first capacitor connection electrode CCE1 may be disposed on the gate insulating layer GI disposed on the buffer layer BF. The first capacitor connection electrode CCE1 may be connected to the first capacitor electrode CPE1 through a first contact hole CT1 penetrating through the gate insulating layer GI, the buffer layer BF, and the second barrier layer BR2.

An interlayer insulating film ILD may be disposed on the third conductive layer CDL3. The interlayer insulating film ILD may include an inorganic film, for example, a silicon nitride layer, a silicon oxynitride layer, a silicon oxide layer, a titanium oxide layer, or an aluminum oxide layer. The interlayer insulating film ILD may include one or more inorganic films.

A fourth conductive layer CDL4 may be disposed on the interlayer insulating film ILD. The fourth conductive layer CDL4 may include a source connection electrode SCE, a drain connection electrode DCE, a gate connection electrode GCE, and/or a second capacitor connection electrode CCE2.

A side of the source connection electrode SCE may be connected to the second light blocking layer BML2 through a second contact hole CT2 penetrating through the interlayer insulating film ILD and the buffer layer BF. Another side of the source connection electrode SCE may be connected to a source electrode SE of the active layer ACT through a third contact hole CT3 penetrating through the interlayer insulating film ILD. The drain connection electrode DCE may be connected to a drain electrode DE of the active layer ACT through a fourth contact hole CT4 penetrating through the interlayer insulating film ILD. The drain connection electrode DCE may be connected to the first capacitor connection electrode CCE1 through a fifth contact hole CT5 penetrating through the interlayer insulating film ILD. The second capacitor connection electrode CCE2 may be connected to the second light blocking layer BML2 acting as the second capacitor electrode through a sixth contact hole CT6 penetrating through the interlayer insulating film ILD and the buffer layer BF.

A first planarization layer VA1 may be disposed on the fourth conductive layer CDL4. For example, the first planarization layer VA1 may be disposed on the source connection electrode SCE, the drain connection electrode DCE, the gate connection electrode GCE, and the second capacitor connection electrode CCE2. For example, the first planarization layer VA1 may include an organic film made of an acryl resin, an epoxy resin, a phenolic resin, a polyamide resin, a polyimide resin, or the like.

A fifth conductive layer CDL5 may be disposed on the first planarization layer VA1. The fifth conductive layer CDL5 may include a pixel connection electrode PCE. A side of the pixel connection electrode PCE may be connected to the source connection electrode SCE through a seventh contact hole CT7 penetrating through the first planarization layer VA1. Another side of the pixel connection electrode PCE may be connected to the second capacitor connection electrode CCE2 through an eighth contact hole CT8 penetrating through the first planarization layer VA1.

A second planarization layer VA2 may be disposed on the fifth conductive layer CDL5. For example, the second planarization layer VA2 may be disposed on the pixel connection electrode PCE. The second planarization layer VA2 and the first planarization layer VA1 may include a same material and may have a same structure.

A light emitting element layer EMTL may be disposed on the second planarization layer VA2. The light emitting element layer EMTL may include a pixel defining film PDL and a light emitting element ED stacked in the third direction DR3. Here, the light emitting element ED may include a pixel electrode PE, a light emitting layer EL, and a common electrode CM.

The pixel electrode PE of the light emitting element ED described above may be disposed on the second planarization layer VA2. The pixel electrode PE may be connected to the pixel connection electrode PCE through a ninth contact hole CT9 penetrating through the second planarization layer VA2.

The light emitting area EA refers to an area in which the pixel electrode PE, the light emitting layer EL, and the common electrode CM are sequentially stacked and holes from the pixel electrode PE and electrons from the common electrode CM are bonded to each other in the light emitting layer EL to emit light. In this case, the pixel electrode PE may be an anode electrode of the light emitting element ED, and the common electrode CM may be a cathode electrode of the light emitting element ED.

In a top emission structure that emits light in a direction of the common electrode CM based on the light emitting layer EL, the pixel electrode may be formed as a single layer made of molybdenum (Mo), titanium (Ti), copper (Cu), or aluminum (Al) or be formed as a stacked structure (Ti/Al/Ti) of aluminum and titanium, a stacked structure (ITO/AI/ITO) of aluminum and ITO, an APC alloy, and a stacked structure (ITO/APC/ITO) of an APC alloy and ITO. The APC alloy may be an alloy of silver (Ag), palladium (Pd), and copper (Cu).

The pixel defining film PDL may define the light emitting areas EA of the pixel. To this end, the pixel defining film PDL may be disposed on the second planarization layer VA2 to expose a partial area of the pixel electrode PE. The pixel defining film PDL may cover (or overlap) each edge of the pixel electrode PE. For example, the pixel defining film PDL may be formed as an organic film made of an acryl resin, an epoxy resin, a phenolic resin, a polyamide resin, a polyimide resin, or the like.

A spacer SPC may be disposed on the pixel defining film PDL. The spacer SPC may serve to support a mask during a process of manufacturing the light emitting layer EL. For example, the spacer SPC may be formed as an organic film made of an acryl resin, an epoxy resin, a phenolic resin, a polyamide resin, or a polyimide resin. In an embodiment, the spacer SPC may be formed integrally with the pixel defining film PDL. In other words, the spacer SPC and the pixel defining film PDL may be made of the same material.

A light emitting layer EL may be disposed on the pixel electrode PE. The light emitting layer EL may include an organic material to emit light of a color (e.g., a predetermined or selectable color). For example, the light emitting layer EL may include a hole transporting layer, an organic material layer, and an electron transporting layer. The organic material layer may include a host and a dopant. The organic material layer may include a material that emits a light (e.g., a predetermined or selectable light) and may be formed of, for example, a phosphorescent material or a fluorescent material.

For example, the organic material layer of the light emitting layer EL that emits light of a third color (e.g., blue) may be a phosphorescent material including a host material including CBP or mCP and including a dopant material including (4,6-F2ppy)2Irpic or L2BD111, but is not limited thereto.

The organic material layer of the light emitting layer EL that emits light of a second color (e.g., green) may be a phosphorescent material including a host material including CBP or mCP and a dopant material including Ir(ppy)3(fac tris(2-phenylpyridine)iridium). As another example, the organic material layer of the light emitting layer EL that emits light of the second color may be a fluorescent material including Alq3(tris(8-hydroxyquinolino)aluminum), but is not limited thereto.

The organic material layer of the light emitting layer EL that emits light of a third color (e.g., red) may be a phosphorescent material including a host material including carbazole biphenyl (CBP) or mCP(1,3-bis(27arbazole-9-yl), and including a dopant containing any one or more selected among PIQIr(acac)(bis(1-phenylisoquinoline) acetylacetonate iridium), PQIr(acac)(bis(1-phenylquinoline)acetylacetonate iridium), PQIr(tris(1-phenylquinoline)iridium), and PtOEP (octaethylporphyrin platinum). As another example, the organic material layer of the light emitting layer EL that emits light of the third color may be a fluorescent material including PBD:Eu(DBM)3(Phen) or perylene, but is not limited thereto.

The common electrode CM may be disposed on the light emitting layer EL. The common electrode CM may be disposed to cover (or overlap) the light emitting layer EL. The common electrode CM may be a common layer commonly disposed on the plurality of light emitting layers EL. A capping layer may be formed on the common electrode CM.

In the top emission structure, the common electrode CM may be formed of a transparent conductive material (TCO) such as ITO or IZO capable of transmitting light, or a semi-transmissive conductive material such as magnesium (Mg), silver (Ag), or an alloy of magnesium (Mg) and silver (Ag). In case that the common electrode CM is formed of the semi-transmissive conductive material, light emission efficiency may be increased by a micro cavity.

The encapsulation layer ENC may be disposed on the light emitting element layer EMTL. The encapsulation layer ENC may include at least one inorganic film to prevent oxygen or moisture from permeating into the light emitting element layer EMTL. The encapsulation layer ENC may include at least one organic film to protect the light emitting element layer EMTL from foreign substances such as dust. For example, the encapsulation layer ENC may include a first encapsulation inorganic film TFE1, an encapsulation organic film TFE2, and a second encapsulation inorganic film TFE3.

The first encapsulation inorganic film TFE1 may be disposed on the common electrode CM, the encapsulation organic film TFE2 may be disposed on the first encapsulation inorganic film TFE1, and the second encapsulation inorganic film TFE3 may be disposed on the encapsulation organic film TFE2. For example, the first encapsulation inorganic film TFE1 and the second encapsulation inorganic film TFE3 may be formed as a multi-film in which one or more inorganic films of a silicon nitride layer, a silicon oxynitride layer, a silicon oxide layer, a titanium oxide layer, and an aluminum oxide layer are alternately stacked. For example, the encapsulation organic film TFE2 may be an organic film made of an acrylic resin, an epoxy resin, a phenolic resin, a polyamide resin, or a polyimide resin.

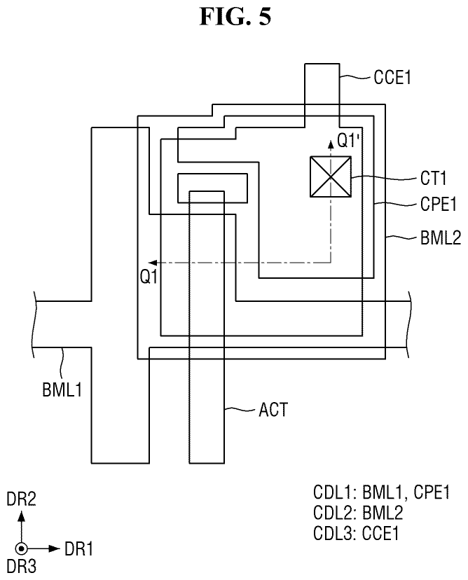

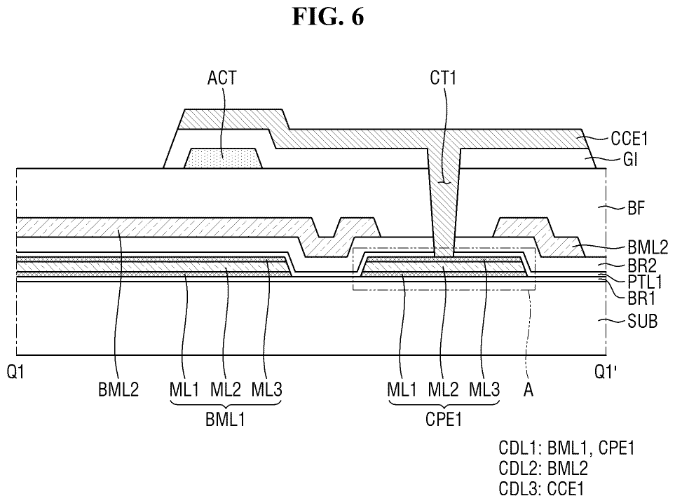

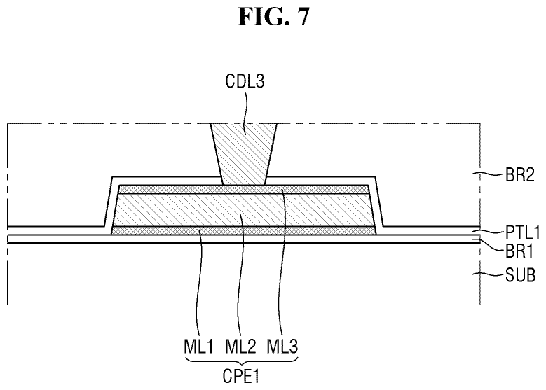

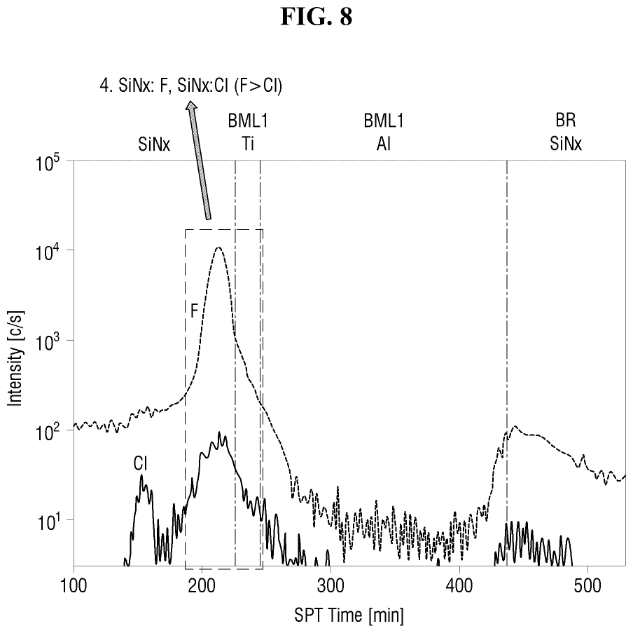

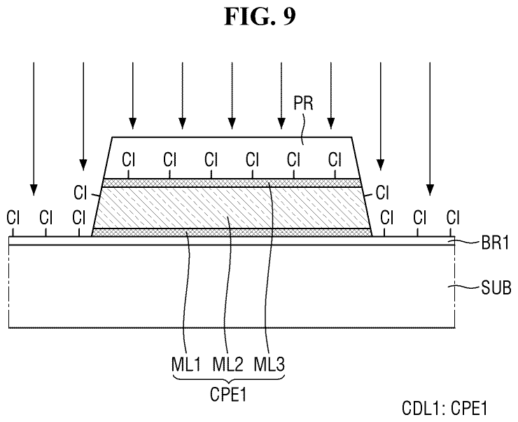

FIG. 5 is a schematic partial plan view of a pixel of the display device according to an embodiment. FIG. 6 is a schematic cross-sectional view taken along line Q1-Q1′ of FIG. 5. FIG. 7 is a schematic enlarged cross-sectional view of area A of FIG. 6. FIG. 8 is a graph illustrating measured concentrations of fluorine and chlorine in a first protective layer and a first conductive layer. FIGS. 9 to 11 are schematic cross-sectional views illustrating each process of a method for manufacturing a first protective layer according to an embodiment.

Referring to FIGS. 5 to 7 in addition to FIG. 4, a first conductive layer CDL1 may be disposed on the first barrier layer BR1. The first conductive layer CDL1 may include a first light blocking layer BML1 and a first capacitor electrode CPE1. The first light blocking layer BML1 and the first capacitor electrode CPE1 may be disposed to be separated from each other. For example, the first light blocking layer BML1 may extend in the first direction DR1 and be continuously disposed in the pixels PX, and the first capacitor electrode CPE1 may be spaced apart from the first light blocking layer BML1 and may have an island pattern.

The first light blocking layer BML1 may be the first power line (VDL in FIG. 3) that transmits the first pixel voltage (ELVDD in FIG. 3). According to the disclosure, by disposing the first capacitor electrode CPE1 to be separated from the first light blocking layer BML1, the first capacitor electrode CPE1 may form the second light blocking layer BML2 and the first capacitor C1. Accordingly, stability of the pixel PX may be improved by increasing a capacitor capacity of the pixel PX.

A second light blocking layer BML2, which is a second conductive layer CDL2, may be disposed on the first light blocking layer BML1 and the first capacitor electrode CPE1. The second light blocking layer BML2 may be disposed to overlap the first light blocking layer BML1 and the first capacitor electrode CPE1. Therefore, the second light blocking layer BML2 may form the first capacitor C1 in an area overlapping the first capacitor electrode CPE1, and may form the second capacitor C2 in an area overlapping the first light blocking layer BML1.

The active layer ACT may be disposed to overlap the first light blocking layer BML1 of the first conductive layer CDL1 and extend in the second direction DR2. The first capacitor connection electrode CCE1 of the third conductive layer CDL3 may be disposed to overlap the active layer ACT, the first light blocking layer BML1, the first capacitor electrode CPE1, and the second light blocking layer BML2.

The first capacitor connection electrode CCE1 of the third conductive layer CDL3 may be connected to the first capacitor electrode CPE1 through the first contact hole CT1. In this case, hydrogen diffusing from the first barrier layer BR1 may diffuse through the first capacitor electrode CPE1 and the first capacitor connection electrode CCE1 and into the active layer ACT adjacent to a lower portion of the first capacitor connection electrode CCE1. Since the active layer ACT is based on oxide, a threshold voltage may shift to a negative side when hydrogen diffuses within the active layer ACT, affecting characteristics of the transistor. For example, a defective bright spot of the pixel PX may occur.

Therefore, according to the embodiment, in order to block diffusion of hydrogen from the first barrier layer BR1, a first conductive layer CDL1 including a first metal layer ML1, a second metal layer ML2, and a third metal layer ML3 may be formed, and a first protective layer PTL1 may be formed on the first conductive layer CDL1.

As illustrated in FIGS. 6 and 7, the first conductive layer CDL1 may include a first metal layer ML1, a second metal layer ML2, and/or a third metal layer ML3. For example, the first light blocking layer BML1 of the first conductive layer CDL1 may include a first metal layer ML1, a second metal layer ML2, and a third metal layer ML3 sequentially stacked on the first barrier layer BR1 in the third direction DR3. The first capacitor electrode CPE1 of the first conductive layer CDL1 may include a first metal layer ML1, a second metal layer ML2, and/or a third metal layer ML3 sequentially stacked on the first barrier layer BR1 in the third direction DR3.

The first metal layer ML1 may be disposed on the first barrier layer BR1. For example, the first metal layer ML1 may be disposed between the first barrier layer BR1 and the second metal layer ML2. The first metal layer ML1 may be made of a material including, for example, titanium (Ti). However, embodiments are not limited thereto.

The second metal layer ML2 may be disposed on the first metal layer ML1. For example, the second metal layer ML2 may be disposed between the first metal layer ML1 and the third metal layer ML3. A thickness of the second metal layer ML2 may be greater than a thickness of the first metal layer ML1 or the third metal layer ML3. Here, the thickness refers to a length in the third direction DR3. The second metal layer ML2 may be made of a material including aluminum (Al), for example.

The third metal layer ML3 may be disposed on the second metal layer ML2. For example, the third metal layer ML3 may be disposed between the second metal layer ML2 and the second barrier layer BR2. The thickness of the third metal layer ML3 may be the same as or greater than the thickness of the first metal layer ML1 described above. The third metal layer ML3 and the above-described first metal layer ML1 may be made of a same material. For example, the third metal layer ML3 may be made of a material including titanium (Ti).

In an embodiment, the above-described first metal layer ML1 and third metal layer ML3 may include titanium. Titanium, which is a material that has the property of capturing hydrogen (H), may block hydrogen diffusing from the lower portion of the first conductive layer CDL1 (e.g., the first light blocking layer BML1 and the first capacitor electrode CPE1).

In an embodiment, the thickness of the first metal layer ML1 may be 100 to 300 Å. In case that the thickness of the first metal layer ML1 is within the above-mentioned range, the first metal layer ML1 may block hydrogen diffusing from the first barrier layer BR1 and prevent conductivity of the first conductive layer CDL1 from decreasing.

The thickness of the third metal layer ML3 may be in a range of about 300 to about 700 Å. In case that the thickness of the third metal layer ML3 is within the above-mentioned range, the third metal layer ML3 may block hydrogen diffusing through the first conductive layer CDL1 and prevent the second metal layer ML2 from being damaged in subsequent processes.

A first protective layer PTL1 may be disposed on the first conductive layer CDL1 and the first barrier layer BR1. The first protective layer PTL1 may be entirely disposed on the first conductive layer CDL1 and the first barrier layer BR1 to cover the first conductive layer CDL1 and the first barrier layer BR1. For example, the first protective layer PTL1 may cover the first light blocking layer BML1 and the first capacitor electrode CPE1.

The first protective layer PTL1 may block hydrogen diffusing from the lower portion. For example, the first protective layer PTL1 may include an insulating material (e.g., an inorganic insulating material) and a first additive added to the insulating material. In an embodiment, the first protective layer PTL1 may include at least one of silicon nitride (SiNx), silicon oxide (SiOₓ), and silicon oxynitride (SiON), and a first additive (or first material) added (e.g., doped or deposited) thereto. As an example, the first protective layer PTL1 may be a silicon nitride layer, a silicon oxide layer, or a silicon oxynitride layer including the first additive. In an embodiment, in case that the first protective layer PTL1 is formed using silicon nitride (SiNx), a barrier effect that blocks diffusion of moisture or hydrogen may be increased.

In an embodiment, the first additive may include at least one of fluorine (F) or chlorine (Cl). As an example, the first protective layer PTL1 may include silicon nitride (SiNₓ:F) to which fluorine (F) is added, silicon nitride (SiNₓ:Cl) to which chlorine (Cl) is added, silicon oxide (SiOₓ:F) or silicon oxynitride (SiON:F) to which fluorine (F) is added, or silicon oxide (SiOₓ:Cl) or silicon oxynitride (SiON:Cl) to which chlorine (Cl) is added.

A concentration of the first additive included in the first protective layer PTL1, for example, fluorine (F) or chlorine (Cl), may be greater than a concentration of fluorine (F) or chlorine (Cl) included in the second barrier layer BR2 on the first protective layer PTL1.

As an example, the first protective layer PTL1 may be silicon nitride (SiNₓ:F, Cl) to which fluorine (F) and chlorine (Cl) are added. In this case, the concentration of fluorine (F) included in the first protective layer PTL1 may be greater than the concentration of chlorine (Cl). The concentration of fluorine and chlorine may gradually increase from an upper surface to a lower surface of the first protective layer PTL1. Since hydrogen may diffuse from the lower portion of the first protective layer PTL1, diffusion of hydrogen may be further blocked by capturing the hydrogen when the concentration of fluorine and chlorine is high in the lower portion of the first protective layer PTL1.

FIG. 8 illustrates concentrations of fluorine (F) and chlorine (Cl) in the first protective layer PTL1 and the first conductive layer CDL1 through secondary ion mass spectroscopy (SIMS) analysis. In the graph of FIG. 8, a horizontal axis represents analysis time and a vertical axis represents concentration. Since SIMS analysis is performed from the upper portion of the first protective layer PTL1 to the lower portion (e.g., in the opposite direction of the thickness direction), the graph of FIG. 8 illustrates the results of measuring the concentrations of fluorine and chlorine while proceeding in the opposite direction of the thickness direction of the first protective layer PTL1 and the first conductive layer CDL1.

As illustrated in FIG. 8, it is illustrated that the concentration of fluorine (F) in the first protective layer PTL1 is greater than the concentration of chlorine (Cl). It is illustrated that the concentrations of fluorine and chlorine gradually increase from the upper surface of the first protective layer PTL1 to the lower surface thereof (from left to right in the graph).

In an embodiment, the thickness of the first protective layer PTL1 may be about 100 Å or less. Accordingly, hydrogen diffusing from the first protective layer PTL1 to the active layer ACT may be blocked, thereby preventing changes in the characteristics of the transistor.

As described above, in an embodiment, hydrogen diffusing from the first barrier layer BR1 and the first conductive layer CDL1 may be blocked by forming the first protective layer PTL1 including the first additive capable of capturing hydrogen and blocking the diffusion of hydrogen. Accordingly, changes in characteristics of the transistor may be prevented and operating characteristics of the transistor may be improved or stabilized.

The above-described first protective layer PTL1 may be manufactured as follows.

Referring to FIG. 9, after stacking a first metal layer material layer, a second metal layer material layer, and a third metal layer material layer on the first barrier layer BR1, a photoresist pattern PR may be formed on the third metal layer material layer. Thereafter, a first conductive layer CDL1 including a first metal layer ML1, a second metal layer ML2, and a third metal layer ML3 may be formed by collectively etching the first metal layer material layer, the second metal layer material layer, and the third metal layer material layer using the photoresist pattern PR as a mask. For example, the first capacitor electrode CPE1 of the first conductive layer CDL1 may include the first metal layer ML1, the second metal layer ML2, and the third metal layer ML3.

The etching process may be performed as a dry etching process. In the etching process, a reaction gas may include Cl₃, BCl₃, N₂ gas, etc. Chlorine (Cl) used as the reaction gas during the etching process may be attached and bonded to surfaces of the first barrier layer BR1 and the first capacitor electrode CPE1.

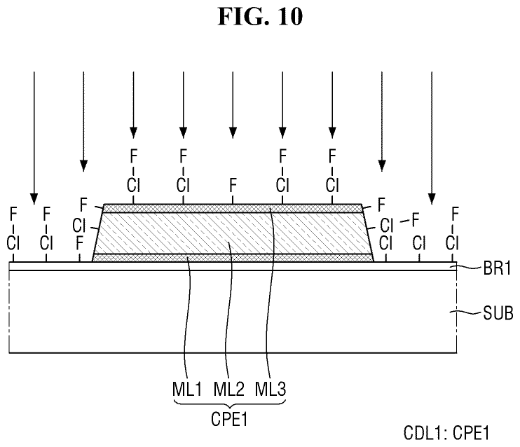

Next, referring to FIG. 10, a cleaning process of cleaning the substrate SUB on which the etching process has been completed is performed. The cleaning process may be a process of removing ions remaining on the substrate SUB after the etching process. In the cleaning process, a cleaning gas may include, for example, O₂ and CF₄ gas. During the cleaning process, some chlorine (Cl) may remain on the first conductive layer CDL1, and fluorine (F) in the cleaning gas may be attached or bonded onto the first barrier layer BR1 and the first conductive layer CDL1. For example, chlorine (Cl) and fluorine (F) may remain on the surfaces of the first barrier layer BR1 and the first conductive layer CDL1.

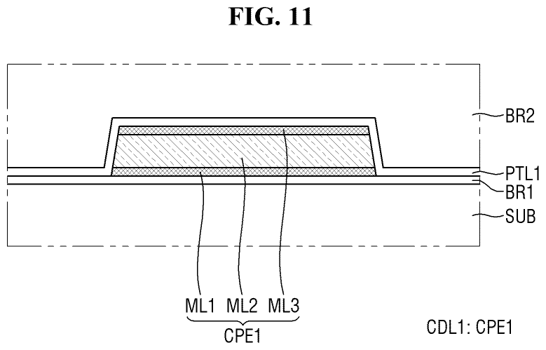

Next, referring to FIG. 11, a second barrier layer BR2 may be formed on the substrate SUB. Specifically, silicon nitride of the second barrier layer BR2 may be deposited on the substrate SUB on which the first barrier layer BR1 and the first conductive layer CDL1 are formed. In this case, the silicon nitride deposited on the substrate SUB may cover (or overlap) fluorine (F) and chlorine (Cl) remaining on the surfaces of the first barrier layer BR1 and the first conductive layer CDL1. A portion of silicon nitride deposited by initially mixing with fluorine (F) and chlorine (Cl) may be formed as the first protective layer PTL1, and a portion where silicon nitride is deposited without fluorine (F) and chlorine (Cl) after the initial stage may be formed as the second barrier layer BR2.

As described above, in the display device 100 according to an embodiment, hydrogen diffusing from the first barrier layer BR1 to the first conductive layer CDL1 may be blocked by forming the first conductive layer CDL1 including the first to third metal layers ML1 to 3. Hydrogen diffusing from the first barrier layer BR1 and the first conductive layer CDL1 may be further blocked by forming the first protective layer PTL1 including fluorine and chlorine on the first barrier layer BR1 and the first conductive layer CDL1. Accordingly, changes in characteristics of the transistor may be prevented and operating characteristics of the transistor may be improved or stabilized.

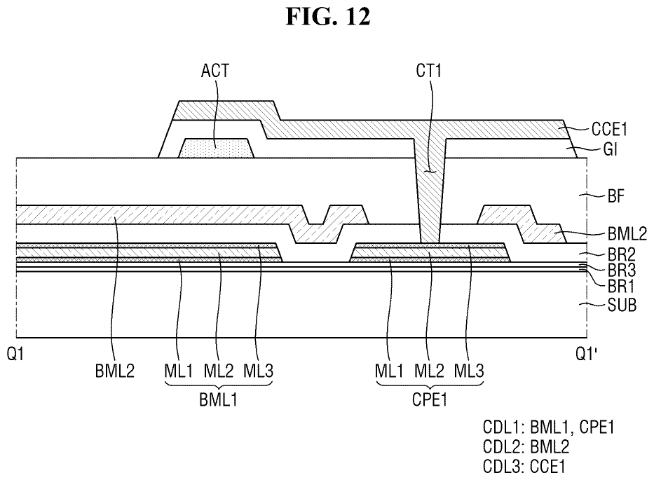

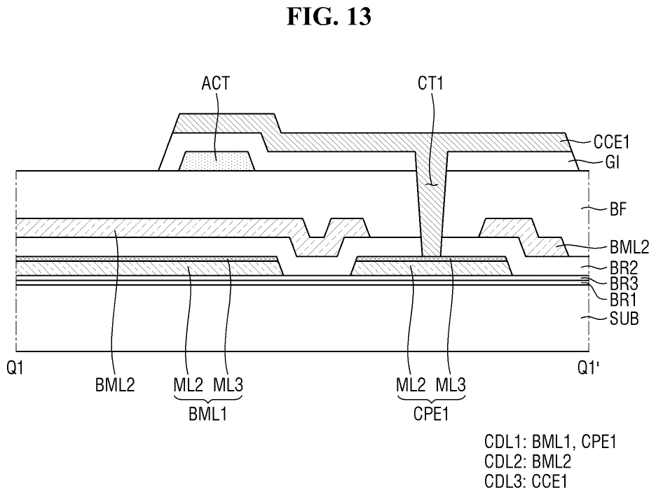

FIG. 12 is a schematic cross-sectional view illustrating a display device according to another embodiment. FIG. 13 is a schematic cross-sectional view illustrating another example of the display device according to another embodiment. FIGS. 12 and 13 illustrate another example of the cross-sectional structure of FIG. 6.

Referring to FIG. 12, the embodiment is different from the embodiments of FIGS. 6 to 11 described above in that the first protective layer PTL1 is omitted and a third barrier layer BR3 is formed between the first conductive layer CDL1 and the first barrier layer BR1. Hereinafter, overlapping descriptions of the same configuration as the above-described embodiment will be omitted and differences from the above-described embodiment will be described.

Referring to FIG. 12, the display device 100 according to an embodiment may include a third barrier layer BR3 disposed between the first barrier layer BR1 and the second barrier layer BR2. The third barrier layer BR3 may be disposed between the first barrier layer BR1 and the first conductive layer CDL1, and an upper surface of the third barrier layer BR3 may be in contact with the lower surface of the second barrier layer BR2 and the lower surface of the first conductive layer CDL1. For example, the third barrier layer BR3 may be in direct contact with the lower surface of the first metal layer ML1 of the first conductive layer CDL1.

The third barrier layer BR3 may include, for example, silicon oxide (SiOₓ). Silicon oxide (SiOx) may improve insulation properties and block hydrogen diffusing from the first barrier layer BR1. For example, in case that the third barrier layer BR3 includes silicon oxide (SiOx), the first barrier layer BR1 may include silicon nitride (SiNx).

As an example, as illustrated in FIG. 13, since the third barrier layer BR3 blocks hydrogen, the first metal layer ML1, which functions to block hydrogen, may be omitted from the first conductive layer CDL1. For example, the first conductive layer CDL1 may include the second metal layer ML2 and the third metal layer ML3. In this case, the second metal layer ML2 is disposed at the lowest portion of the first conductive layer CDL1, so that the third barrier layer BR3 and the second metal layer ML2 may be in direct contact with each other.

In the embodiment, by covering the first barrier layer BR1 with a third barrier layer BR3 including silicon oxide (SiOx), which may have a desirable characteristics in blocking hydrogen, it is possible to effectively block hydrogen from diffusing upward from the first barrier layer BR1. Accordingly, changes in characteristics of the transistor may be prevented and operating characteristics of the transistor may be improved or stabilized.

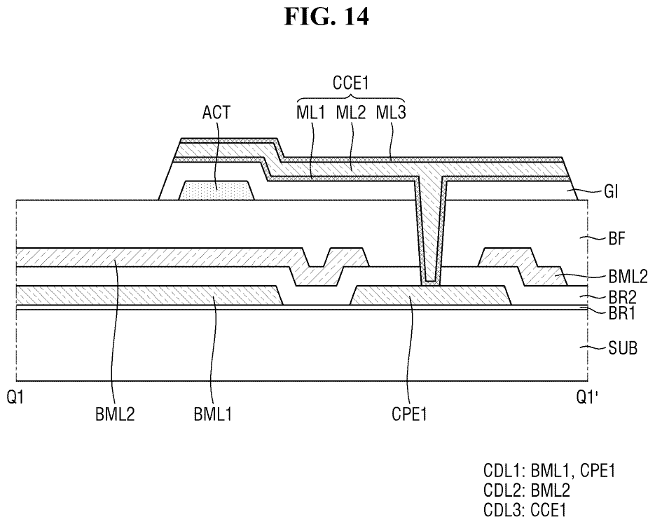

FIG. 14 is a cross-sectional view illustrating a display device according to still another embodiment. FIG. 14 illustrates another example of the cross-sectional structure of FIG. 6.

Referring to FIG. 14, the embodiment is different from the embodiments of FIGS. 6 to 13 described above at least in that a third conductive layer CDL3 includes a first metal layer ML1, a second metal layer ML2, and a third metal layer ML3. Hereinafter, repetitive descriptions of the same configuration as the above-described embodiment will be omitted and differences from the above-described embodiment will be described.

Referring to FIG. 13, the display device 100 according to an embodiment may include a third conductive layer CDL3 including a first metal layer ML1, a second metal layer ML2, and a third metal layer ML3. For example, a first capacitor electrode CPE1 of the third conductive layer CDL3 may include a first metal layer ML1, a second metal layer ML2, and a third metal layer ML3 sequentially stacked on the gate insulating layer GI in the third direction DR3.

The first metal layer ML1 may be disposed on the gate insulating layer GI. The first metal layer ML1 may be disposed on the first capacitor electrode CPE1 in the first contact hole CT1. For example, the first metal layer ML1 may be disposed between the gate insulating layer GI and the second metal layer ML2. The first metal layer ML1 may be made of, for example, a material including titanium (Ti).

The second metal layer ML2 may be disposed on the first metal layer ML1. For example, the second metal layer ML2 may be disposed between the first metal layer ML1 and the third metal layer ML3. A thickness of the second metal layer ML2 may be greater than a thickness of the first metal layer ML1 or the third metal layer ML3. The second metal layer ML2 may be made of a material including aluminum (Al), for example.

The third metal layer ML3 may be disposed on the second metal layer ML2. The thickness of the third metal layer ML3 may be the same as or greater than the thickness of the first metal layer ML1 described above. The third metal layer ML3 and the above-described first metal layer ML1 may be made of a same material. For example, the third metal layer ML3 may be made of a material including titanium (Ti).

The above-described first metal layer ML1 and third metal layer ML3 may include titanium. Titanium, which is a material that has the property of capturing hydrogen (H), may block hydrogen diffusing from the lower portion through the first conductive layer CDL1 (e.g., the first capacitor electrode CPE1).

In an embodiment, the thickness of the first metal layer ML1 may be in a range of about 200 to about 500 Å. In case that the thickness of the first metal layer ML1 is within the above-mentioned range, the first metal layer ML1 may block hydrogen diffusing from the first capacitor electrode CPE1 and prevent conductivity of the third conductive layer CDL3 from decreasing.

As described above, in an embodiment, hydrogen diffusing through the first capacitor electrode CPE1 may be blocked by forming the third conductive layer CDL3 including the first to third metal layers ML1 to ML3. Accordingly, changes in characteristics of the transistor may be prevented and operating characteristics of the transistor may be improved or stabilized.

It is illustrated in the embodiment of FIG. 14 that the first conductive layer CDL1 is formed as a single layer, but the disclosure is not limited thereto, and may be applied to a case in which the first conductive layer CDL1 includes the first to third metal layers ML1 to ML3 as illustrated in FIG. 6 and may also be applied to a case including the third barrier layer BR3 of FIG. 11.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first barrier layer disposed on a substrate;
a first conductive layer disposed on the first barrier layer and including a first light blocking layer and a first capacitor electrode;
a protective layer disposed on the first conductive layer and including a first additive;
a second barrier layer disposed on the protective layer;
a second conductive layer disposed on the second barrier layer;
a buffer layer disposed on the second conductive layer;
an active layer disposed on the buffer layer and including an oxide semiconductor;
a gate insulating layer disposed on the active layer; and
a third conductive layer disposed on the gate insulating layer and connected to the first capacitor electrode,
wherein the first conductive layer includes a first metal layer, a second metal layer disposed on the first metal layer, and a third metal layer disposed on the second metal layer.

2. The display device of claim 1, wherein
the first metal layer includes titanium, the second metal layer includes aluminum, and
the third metal layer includes titanium.

3. The display device of claim 1, wherein the second metal layer has a thickness greater than each of the first metal layer and the third metal layer.

4. The display device of claim 1, wherein
a thickness of the first metal layer is in a range of about 100 to about 300 Å, and
a thickness of the third metal layer is in a range of about 300 to about 700 Å.

5. The display device of claim 1, wherein the first additive includes fluorine and chlorine.

6. The display device of claim 5, wherein a concentration of fluorine in the protective layer is greater than a concentration of chlorine.

7. The display device of claim 5, wherein a concentration of fluorine and a concentration of chlorine in the protective layer increases from an upper surface to a lower surface of the protective layer.

8. The display device of claim 5, wherein the protective layer contains silicon nitride including fluorine and chlorine.

9. The display device of claim 1, wherein
the first light blocking layer and the first capacitor electrode are separated from each other, and
the first capacitor electrode has an island pattern.

10. A display device comprising:
a first barrier layer disposed on a substrate;
a second barrier layer disposed on the first barrier layer;
a first conductive layer disposed on the second barrier layer and including a first light blocking layer and a first capacitor electrode;
a third barrier layer disposed on the first conductive layer;
a second conductive layer disposed on the third barrier layer;
a buffer layer disposed on the second conductive layer;
an active layer disposed on the buffer layer and including an oxide semiconductor;
a gate insulating layer disposed on the active layer; and
a third conductive layer disposed on the gate insulating layer and connected to the first capacitor electrode,
wherein the first conductive layer includes a first metal layer and a second metal layer disposed on the first metal layer.

11. The display device of claim 10, wherein
the first barrier layer includes silicon nitride, and
the second barrier layer includes silicon oxide.

12. The display device of claim 11, wherein
the first metal layer includes aluminum, and
the second metal layer includes titanium.

13. The display device of claim 11, wherein a thickness of the second metal layer is in a range of about 300 to about 700 Å.

14. The display device of claim 11, further comprising:
a third metal layer disposed on a lower portion of the first metal layer,
wherein the third metal layer includes titanium.

15. A display device comprising:
a first barrier layer disposed on a substrate;
a first conductive layer disposed on the first barrier layer and including a first light blocking layer and a first capacitor electrode;
a second barrier layer disposed on the first conductive layer;
a second conductive layer disposed on the second barrier layer;
a buffer layer disposed on the second conductive layer;
an active layer disposed on the buffer layer and including an oxide semiconductor;
a gate insulating layer disposed on the active layer; and
a third conductive layer disposed on the gate insulating layer and connected to the first capacitor electrode,
wherein the third conductive layer includes a first metal layer, a second metal layer disposed on the first metal layer, and a third metal layer disposed on the second metal layer.

16. The display device of claim 15, wherein
the first metal layer includes titanium,
the second metal layer includes aluminum, and
the third metal layer includes titanium.

17. The display device of claim 15, wherein the second metal layer has a thickness greater than each of the first metal layer and the third metal layer.

18. The display device of claim 15, wherein
a thickness of the first metal layer is in a range of about 200 to about 500 Å, and
a thickness of the third metal layer is in a range of about 300 to about 700 Å.

19. The display device of claim 15, wherein the active layer includes indium-gallium-zinc oxide, indium-gallium-zinc-tin oxide, or indium-gallium oxide.

20. The display device of claim 15, wherein
the first light blocking layer and the first capacitor electrode are separated from each other, and
the first capacitor electrode has an island pattern.
